(19) United States
(12) Patent Application Publication
(10) Pub. No.: US 2007/0025089 A1
(43) Pub. Date: Feb. 1, 2007

(54) Heat-dissipating device and method for radiating heat via natural convection

(75) Inventors: Jui-Yuan Hsu, Taoyuan Hsien (TW); Shih-Kai Chien, Taoyuan Hsien (TW); Wen-Yi Yeh, Taoyuan Hsien (TW)

Correspondence Address: MADSON & AUSTIN;GATEWAY TOWER WEST, SUITE 900, 15 WEST SOUTH TEMPLE, SALT LAKE CITY, UT, 84101, US

(73) Assignee: Delta Electronics, Inc.

(21) Appl. No.: 11/327,250

(22) Filed: Jan. 6, 2006

(30) Foreign Application Priority Data
Jul. 29, 2005 (TW) 094125932

(51) Int. Cl. H05K 7/20

(52) U.S. Cl. 361/719

(57) ABSTRACT

A heat-dissipating device for radiating heat to the ambient air via natural convection includes a thermally conductive plate and a radiation-enhancing layer. The thermally conductive plate is mounted on a circuit board. The radiation-enhancing layer is attached onto a surface of the thermally conductive plate and having a higher emissivity than the thermally conductive plate. By means of such a structure of the heat-dissipating device, the heat generated from an electronic component on the circuit board is successively conducted to the thermally conductive plate, transferred to the radiation-enhancing layer and radiated from the radiation-enhancing layer to the ambient air via natural convection.

### FIELD OF THE INVENTION

The present invention relates to a heat-dissipating device and a heat-dissipation method, and more particularly to a heat-dissipating device and a heat-dissipation method for enhancing the efficacy of radiating heat to the ambient air via natural convection.

### BACKGROUND OF THE INVENTION

Recently, planar displays such as liquid crystal displays (LCD) became indispensable to our lives. A liquid crystal display usually has a power supply apparatus for offering the required operating power. When the power supply apparatus operates, the electronic components on the printed circuit board thereof may generate energy in the form of heat, which is readily accumulated around the circuit board and difficult to dissipate away. If the power supply apparatus fails to transfer enough heat to the ambient air, the elevated operating temperature may result in damage of the electronic components, a breakdown of the whole power supply apparatus or reduced operation efficiency. Therefore, it is important to dissipate the heat generated from the electronic components in order to stabilize the operation and extend the operational life.

For most electronic devices, forced convention is employed to remove heat by using a fan to cool the electronic components. Since the planar display is developed toward minimization, the electronic device with the large fan fails to meet the requirement of small size, light weightiness and easy portability. In other words, the large fan should be exempted from the planar display and thus natural convention may be taken into consideration. Referring to FIG. 1, a heat-dissipating device for removing the heat generated from the electronic components via natural convention is illustrated. The heat-dissipating device of FIG. 1 is for example applied to a power supply apparatus of a liquid crystal display. As shown in FIG. 1, several electronic components 12, 13 and 14 are mounted on a circuit board 11. The electronic component 12 is in contact with a surface of the heat-dissipating device 15 and optionally screwed onto the heat-dissipating device 15. The electronic components 13 and 14 are arranged in the vicinity of the heat-dissipating device 15. The heat generated from the electronic component 12 during operation will be conducted to the heat-dissipating device 15, and then spread over the surface of the heat-dissipating device 15. Subsequently, the heat is radiated from the surface of the heat-dissipating device 15 to the ambient air via natural convection.

If a hot object at a temperature T₁ (K) is radiating energy to its cooler surroundings at temperature T₂ (K), the Stefan-Boltzmann equation is expressed in the form of:
Qr=Aεσ(T₁⁴-T₂⁴)
where Qr is the net radiation power (W), A is the total radiating area (m²),ε is the emissivity of the object (ε=1 for ideal radiator), σ is the Stefan-Boltzmann constant (5.676×10⁻⁸ W/m²K⁴).

From the above equation, it is found that the net radiation power is a function of the emissivity. Typically, the heat-dissipating device 15 is made of aluminum or aluminum alloy, which has an emissivity of about 0.05. This small emissivity contributes to a low net radiation power. That is to say, even though the heat-dissipating device 15 has high thermal conductivity to conduct heat from the electronic component 12, the efficacy of radiating heat from the surface of the heat-dissipating device 15 to the ambient air via natural convection is unsatisfactory.

In order to enhance the net radiation power, the heat-dissipating device is usually subject to an anodizing treatment, as is illustrated in the flowchart of FIG. 2. Firstly, a heat-dissipating device is provided (Step S11). Then, the heat-dissipating device is dipped into an electroplating tank to perform an anodizing treatment on the surface of the heat-dissipating device (Step S12). Afterward, the anodized heat-dissipating device is mounted on a circuit board, thereby radiating the heat from the surface of the heat-dissipating device to the ambient air via natural convection (Step S13).

The anodizing treatment allows for oxidation of the aluminum or aluminum alloy at the surface of the heat-dissipating device into aluminum oxide, so that the emissivity is increased. The anodizing treatment of the heat-dissipating device, however, has some drawbacks. For example, the use of anodizing treatment is neither cost-effective nor environmentally friendly. In addition, since the anodizing treatment should be precisely controlled, the application thereof is limited.

In views of the above-described disadvantages resulted from the prior art, the applicant keeps on carving unflaggingly to develop a heat-dissipating device and a heat-dissipation method according to the present invention through wholehearted experience and research.

### SUMMARY OF THE INVENTION

It is an object of the present invention to provide a heat-dissipating device and a heat-dissipation method for enhancing the efficacy of radiating heat to the ambient air via natural convection.

Another object of the present invention is to provide cost-effective, easily controlled and environmentally friendly heat-dissipating device and method.

In accordance with a first aspect of the present invention, there is provided a method for enhancing the efficacy of radiating heat to the ambient air via natural convection. Firstly, a thermally conductive plate is provided. Then, a radiation-enhancing layer is attached onto a surface of the thermally conductive plate, wherein the radiation-enhancing layer has a higher emissivity than the thermally conductive plate. Afterwards, a combination of the thermally conductive plate and the radiation-enhancing layer is mounted on a circuit board, so that the heat generated from an electronic component on the circuit board is successively conducted to the thermally conductive plate, transferred to the radiation-enhancing layer and radiated from the radiation-enhancing layer to the ambient air via natural convection.

Preferably, the thermally conductive plate is made of a metallic material such as aluminum and aluminum alloy.

In an embodiment, the radiation-enhancing layer is made of a nonmetallic material.

In an embodiment, the radiation-enhancing layer is formed as a sticker paper.

In an embodiment, the radiation-enhancing layer is formed as sticker cloth.

In an embodiment, the radiation-enhancing layer is black in color.

In an embodiment, the thermally conductive plate and the radiation-enhancing layer have a plurality of holes aligned with each other, so that the efficacy of radiating heat to the ambient air via natural convection is further enhanced.

In an embodiment, the electronic component on the circuit board is in contact with the thermally conductive plate.

In accordance with a first aspect of the present invention, there is provided a heat-dissipating device for radiating heat to the ambient air via natural convection. The heat-dissipating device comprises a thermally conductive plate and a radiation-enhancing layer. The thermally conductive plate is mounted on a circuit board. The radiation-enhancing layer is attached onto a surface of the thermally conductive plate and having a higher emissivity than that of the thermally conductive plate. By means of such a structure of the heat-dissipating device, the heat generated from an electronic component on the circuit board is successively conducted to the thermally conductive plate, transferred to the radiation-enhancing layer and radiated from the radiation-enhancing layer to the ambient air via natural convection.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a schematic view illustrating a heat-dissipating device for removing the heat generated from the electronic components via natural convention;

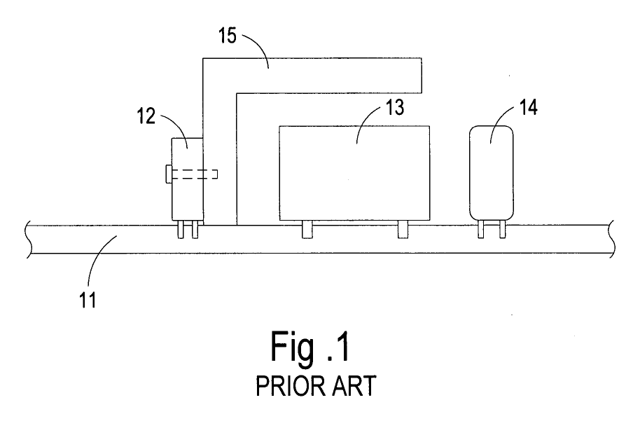

FIG. 2 is a flowchart illustrating the implementation of using a heat-dissipating device after an anodizing treatment;

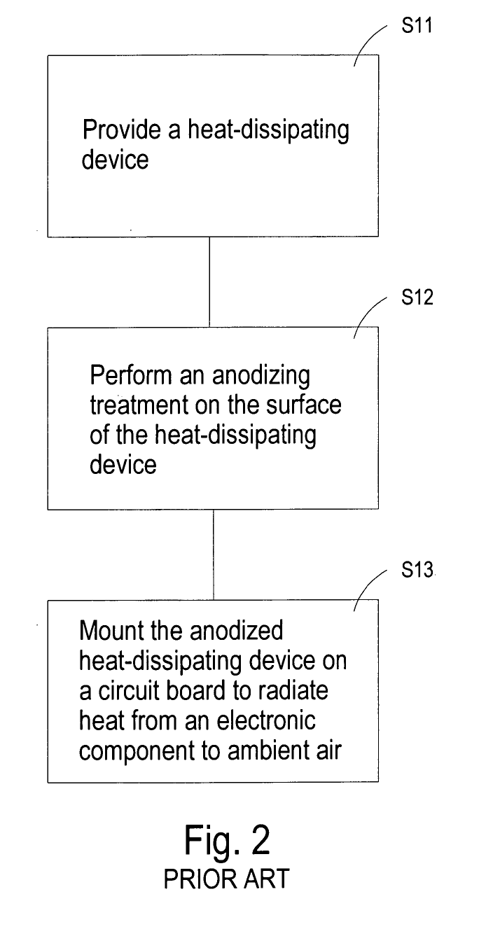

FIG. 3 is a schematic view illustrating a heat-dissipating device for removing the heat generated from the electronic components via natural convention according to a preferred embodiment of the present invention;

FIG. 4 is a schematic view illustrating a heat-dissipating device for removing the heat generated from the electronic components via natural convention according to another preferred embodiment of the present invention; and

FIG. 5 is a flowchart illustrating the implementation of using the heat-dissipating device of the present invention to remove the heat generated from the electronic components via natural convention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

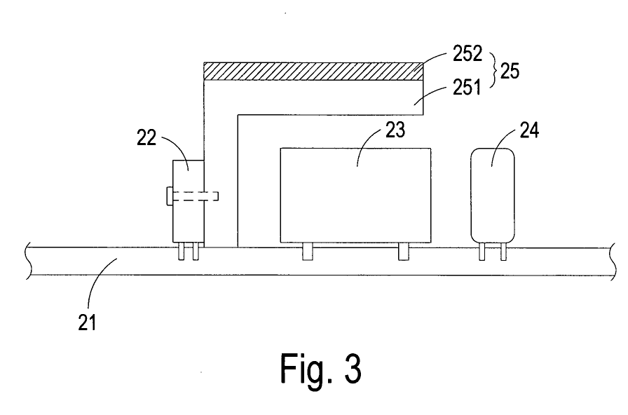

Referring to FIG. 3, a heat-dissipating device for removing the heat generated from the electronic components via natural convention according to a preferred embodiment of the present invention is illustrated. As shown in FIG. 3, several electronic components 22, 23 and 24 such as transistors, resistors or capacitors are mounted on a circuit board 21. The heat-dissipating device 25 comprises a thermally conductive plate 251 and a radiation-enhancing layer 252. The electronic component 22 is in contact with a surface of the thermally conductive plate 251 and optionally screwed onto the thermally conductive plate 251. The electronic components 23 and 24 are arranged in the vicinity of the heat-dissipating device 25. In this embodiment, the thermally conductive plate 251 is made of the material with high thermal conductivity, for example aluminum or aluminum alloy.

The radiation-enhancing layer 252 is attached onto the top surface or other portion of the thermally conductive plate 251. Especially, the radiation-enhancing layer 252 is made of the material with higher emissivity than that of the thermally conductive plate 251, for example nonmetallic material. It is preferred that the radiation-enhancing layer 252 is formed as a sticker paper or sticker cloth to be directly bonded to the thermally conductive plate 251. Moreover, the radiation-enhancing layer 252 is preferably black or grey in color.

The heat generated from the electronic component 22 during operation will be firstly conducted to the thermally conductive plate 251, and then spread over the surface of the thermally conductive plate 251. Subsequently, most heat will be conducted to the radiation-enhancing layer 252, and then radiated from the surface of the radiation-enhancing layer 252 to the ambient air via natural convection.

According to the Stefan-Boltzmann equation described above, the net radiation power is proportioned to the emissivity of the hot object under the same conditions (i.e. the total radiating area A, and the temperatures T₁ and T₂ are identical). In a preferred embodiment, the emissivity of the radiation-enhancing layer 252 is ranged between 0.7 and 0.9, which is much larger than the emissivity of the thermally conductive plate 251 (e.g. 0.05). Due to the high emissivity of the radiation-enhancing layer 252, the efficacy of radiating heat to the ambient air via natural convection will be largely increased. The experiments demonstrate that the working temperature of electronic component 22 is further reduced by 3 to 12° C. when the heat-dissipating device 25 of the present invention is used in replace of the conventional heat-dissipating device. In addition, the working temperature of electronic component 23 or 24 is also reduced.

Due to the high thermal conductivity of the thermally conductive plate 251 and the high emissivity of the radiation-enhancing layer 252, the heat-dissipating device 25 of this embodiment has the functions of quickly conducting the heat generated from the electronic components and effectively radiating the heat to the ambient air via natural convection. As previously described, the anodizing treatment of the heat-dissipating device in the prior art has many disadvantages. According to the present invention, the radiation-enhancing layer 252 is simple, cost-effective and environmentally friendly. The area, the size and the locations of the radiation-enhancing layer 252 can be predetermined, and then the combination of the thermally conductive plate 251 and the radiation-enhancing layer 252 is mounted to the circuit board 21. Alternatively, the area, the size and the locations of the radiation-enhancing layer 252 may be adjusted after the thermally conductive plate 251 is mounted to the circuit board 21 so as to increase the utility flexibility.

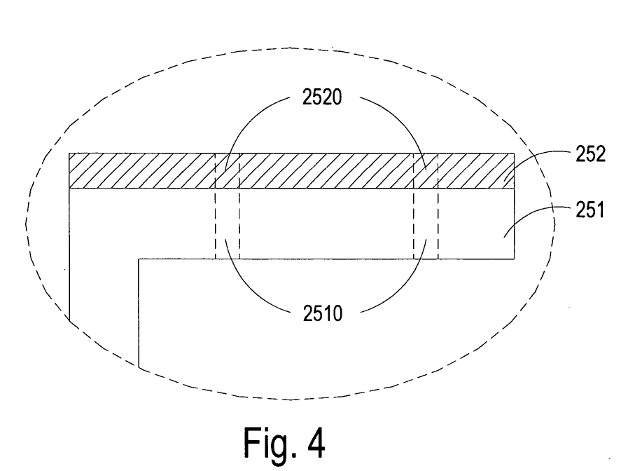

A further embodiment of a heat-dissipating device is illustrated in FIG. 4. In this embodiment, the thermally conductive plate 251 and the radiation-enhancing layer 252 included therein are similar to those shown in FIG. 3, and are not to be redundantly described herein. In addition, the thermally conductive plate 251 and the radiation-enhancing layer 252 have a plurality of holes 2510 and 2520 aligned with each other, so that the efficacy of radiating heat to the ambient air via natural convection is further enhanced.

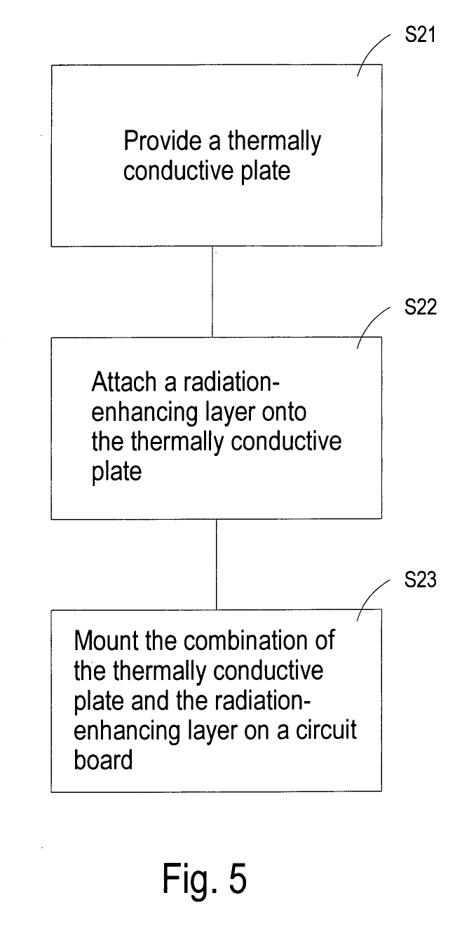

The process of using the heat-dissipating device of the present invention to remove the heat generated from the electronic components via natural convention will be illustrated with reference to the flowchart of FIG. 5. Firstly, a thermally conductive plate is provided (Step S21). Then, a radiation-enhancing layer is attached onto a surface of the thermally conductive plate (Step S22). Afterward, the combination of the thermally conductive plate and the radiation-enhancing layer is mounted on a circuit board, thereby radiating the heat from the surface of the heat-dissipating device to the ambient air via natural convection (Step S23).

From the above description, the heat-dissipating device and the heat-dissipation method of the present invention are capable of enhancing the efficacy of radiating heat to the ambient air via natural convection. In addition, using the radiation-enhancing layer to increase the emissivity of the heat-dissipating device is simple and more cost-effective and environmentally friendly when compared with the conventional anodizing treatment. Moreover, since the area, the size and the locations of the radiation-enhancing layer may be adjusted after the thermally conductive plate is mounted to the circuit board, the utility flexibility of the heat-dissipating device is also increased.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method for enhancing the efficacy of radiating heat to the ambient air via natural convection, comprising steps of:
providing a thermally conductive plate;
attaching a radiation-enhancing layer onto a surface of said thermally conductive plate, wherein said radiation-enhancing layer has a higher emissivity than said thermally conductive plate; and
mounting a combination of said thermally conductive plate and said radiation-enhancing layer on a circuit board, so that the heat generated from an electronic component on said circuit board is successively conducted to said thermally conductive plate, transferred to said radiation-enhancing layer and radiated from said radiation-enhancing layer to the ambient air via natural convection.

2. The method according to claim 1 wherein said thermally conductive plate is made of a metallic material selected from a group consisting of aluminum and aluminum alloy.

3. The method according to claim 1 wherein said radiation-enhancing layer is made of a nonmetallic material.

4. The method according to claim 1 wherein said radiation-enhancing layer is formed as a sticker paper.

5. The method according to claim 1 wherein said radiation-enhancing layer is formed as sticker cloth.

6. The method according to claim 1 wherein said radiation-enhancing layer is black in color.

7. The method according to claim 1 wherein said thermally conductive plate and said radiation-enhancing layer have a plurality of holes aligned with each other, so that the efficacy of radiating heat to the ambient air via natural convection is further enhanced.

8. The method according to claim 1 wherein said electronic component on said circuit board is in contact with said thermally conductive plate.

9. A heat-dissipating device for radiating heat to the ambient air via natural convection, comprising:
a thermally conductive plate mounted on a circuit board; and
a radiation-enhancing layer attached onto a surface of said thermally conductive plate and having a higher emissivity than said thermally conductive plate, wherein the heat generated from an electronic component on said circuit board is successively conducted to said thermally conductive plate, transferred to said radiation-enhancing layer and radiated from said radiation-enhancing layer to the ambient air via natural convection.

10. The heat-dissipating device according to claim 9 wherein said thermally conductive plate is made of a metallic material selected from a group consisting of aluminum and aluminum alloy.

11. The heat-dissipating device according to claim 9 wherein said radiation-enhancing layer is made of a nonmetallic material.

12. The heat-dissipating device according to claim 9 wherein said radiation-enhancing layer is formed as a sticker paper.

13. The heat-dissipating device according to claim 9 wherein said radiation-enhancing layer is formed as sticker cloth.

14. The heat-dissipating device according to claim 9 wherein said radiation-enhancing layer is black in color.

15. The heat-dissipating device according to claim 9 wherein said thermally conductive plate and said radiation-enhancing layer have a plurality of holes aligned with each other, so that the efficacy of radiating heat to the ambient air via natural convection is further enhanced.

16. The heat-dissipating device according to claim 9 wherein said electronic component on said circuit board is in contact with said thermally conductive plate.
